(19) United States
(12) Patent Application Publication
(10) Pub. No.: US 2007/0065581 A1
(43) Pub. Date: Mar. 22, 2007

(54) Substrate processing system and method

(75) Inventor: Hirotsugu Shiraiwa, Tsukui-gun (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 11/523,602

(22) Filed: Sep. 20, 2006

(30) Foreign Application Priority Data
Sep. 22, 2005 (JP) 2005-276294

(51) Int. Cl. C23C 16/00; H01L 21/306

(52) U.S. Cl. 427/255.5; 118/719; 156/345.32

(57) ABSTRACT

A substrate processing system includes: a processing chamber where a substrate is processed; and a carrier device carrying the substrate to/from the processing chamber, wherein the carrier device includes at least two arms each capable of holding a substrate and is capable of switching a state of making the two arms simultaneously enter the processing chamber and a state of making the two arms leave the processing chamber at different timings.

### BACKGROUND OF THE INVENTION

1. Field of the Invention

The present invention relates to a substrate processing system and a substrate processing method that use a plurality of chambers such as a load lock chamber and substrate processing chambers, and a carrier chamber for carrying a substrate between the plural chambers.

2. Description of the Related Art

There have conventionally been disclosed various substrate processing methods and apparatuses for processing a substrate such as a LCD (liquid crystal display) and a semiconductor wafer. For example, Japanese Patent Application Laid-open No. 2001-160584 discloses a multi-chamber substrate processing system in which a load lock chamber for loading/unloading a substrate and various substrate processing chambers and the like where the loaded substrate is subjected to substrate processing such as etching under a reduced-pressure atmosphere are disposed to surround a carrier chamber carrying the substrate.

In such a multi-chamber substrate processing system, various techniques to improve throughput of an apparatus are used. For example, in the substrate processing system described in the aforesaid patent document 1, a two-stage support member capable of supporting two substrates at one time is provided in each of the substrate processing chambers, so that by only one advancement movement of a substrate carrier arm into each of the substrate processing chambers, it is possible to replace a processed substrate by an unprocessed substrate.

### SUMMARY OF THE INVENTION

In the substrate processing chamber using the two-stage support member described in the aforesaid patent document 1, substrates can be loaded and unloaded simultaneously to/from the two-stage support member, but complicating the inside of the chamber is not desirable for some kind of substrate processing such as a CVD process, and therefore, it is not sometimes desirable to simultaneously handle substrates on the two-stage support member. For such substrate processing, a substrate processing chamber using a single-stage support member is generally used.

In the substrate processing chamber thus using the single-stage support member, the loading of a substrate and the unloading of a substrate to/from the single-stage support member take place at different timings. Therefore, if, as in conventional substrate processing system and method, a uniform method is used for the substrate loading/unloading in a substrate processing system including both a single-stage substrate processing chamber and a two-stage substrate processing chamber, the loading of a substrate and the unloading of a substrate take place stage by stage not only in the single-stage substrate processing chamber but also in the two-stage substrate processing chamber, which lowers throughput.

The present invention was made in view of the above problem, and an object thereof is to use the optimum substrate loading/unloading method according to the kind of chambers in a multi-chamber substrate processing system in which one single-stage substrate processing chamber or more and one two-stage substrate processing chamber or more can both exist, to thereby provide a substrate processing system and a substrate processing method with improved throughput.

In order to solve the above problem, according to the present invention, provided is a substrate processing system including: a substrate processing chamber where a substrate is processed; and a carrier device carrying the substrate to/from the processing chamber, wherein the carrier device includes at least two arms each capable of holding a substrate and is capable of switching a state of making the two arms enter the processing chamber simultaneously and a state of making the two arms enter the processing chamber at different timings.

In the substrate processing system, the processing chamber may be provided in plurality, and the two arms may be made to simultaneously enter part of the processing chambers and the two arms may be made to enter the other part of the processing chambers at different timings.

According to another aspect of the present invention, provided is a substrate processing method using a substrate processing system that includes: a processing chamber where a substrate is processed; and a carrier device carrying the substrate to/from the processing chamber, wherein the carrier device includes at least two arms each capable of holding a substrate and is capable of switching a state of making the two arms simultaneously enter the processing chamber and a state of making the two arms enter the processing chamber at different timings, and wherein steps of making the two arms enter the processing chamber coincide with each other.

In the substrate processing method, steps of making the two arms leave the processing chamber may coincide with each other.

According to still another aspect of the present invention, provided is a substrate processing method using a substrate processing system that includes: a processing chamber where a substrate is processed; and a carrier device carrying the substrate to/from the processing chamber, wherein the carrier device includes at least two arms each capable of holding a substrate and is capable of switching a state of making the two arms simultaneously enter the processing chamber and a state of making the two arms enter the processing chamber at different timings, and wherein steps of making the two arms enter the processing chamber take place at different timings.

In the substrate processing method, a step of making one of the two arms enter the processing chamber and a step of making the other arm leave the processing chamber may coincide with each other. Further, a step of making one of the two arms enter the processing chamber and a step of making the other arm leave the processing chamber may take place at different timings.

According to yet another aspect of the present invention, provided is a substrate processing method using a substrate processing system that includes: a plurality of processing chambers in each of which a substrate is processed; and a carrier device carrying the substrate to/from the processing chambers, wherein the carrier device includes at least two arms each capable of holding a substrate and is capable of switching a state of making the two arms simultaneously enter each of the processing chambers and a state of making the two arms enter each of the processing chambers at different timings, and wherein the two arms are made to simultaneously enter part of the processing chambers and the two arms are made to enter the other part of the processing chambers at different timings.

In the substrate processing method, a step of making one of the two arms enter the other part of the processing chambers and a step of making the other arm leave the other part of the processing chambers may coincide with each other. Further, a step of making one of the two arms enter the other part of the processing chambers and a step of making the other arm leave the other part of the processing chambers may take place at different timings.

According to the present invention, the optimum substrate loading/unloading method is used according to the kind of chambers in a multi-chamber substrate processing system in which one single-stage substrate processing chamber or more and one two-stage substrate processing chamber or more can both exist, so that throughput can be improved.

### BRIEF DESCRIPTION OF THE DRAWINGS

FIG. 1 is a schematic plane view showing the configuration of a substrate processing system according to an embodiment of the present invention;

FIG. 2 is a schematic side view showing the configuration of the substrate processing system according to the embodiment of the present invention;

FIG. 3 is a schematic perspective view showing a carrier device;

FIG. 4 is a schematic perspective view showing a two-stage load lock chamber;

FIG. 5 is a schematic perspective view showing a single-stage mounting table;

FIG. 6 is a schematic perspective view showing a two-stage mounting table;

FIG. 7 is a view showing substrate replacement on the single-stage mounting table;

FIG. 8 is a view showing the substrate replacement on the single-stage mounting table;

FIG. 9 is a view showing the substrate replacement on the single-stage mounting table;

FIG. 10(a) and FIG. 10(b) are views showing two-stage pins of the two-stage mounting table;

FIG. 11 is a view showing substrate replacement on the two-stage mounting table;

FIG. 12 is a view showing the substrate replacement on the two-stage mounting table;

FIG. 13 is a view showing the substrate replacement on the two-stage mounting table;

FIG. 14(a) to FIG. 14(d) are views showing a first procedure of the present invention for substrate replacement in a two-stage chamber;

FIG. 15(a) to FIG. 15(f) are views showing a second procedure of the present invention for substrate replacement on the two-stage chamber; and

FIG. 16(a) to FIG. 16(g) are views showing a third procedure of the present invention for substrate replacement in a single-stage chamber.

### DETAILED DESCRIPTION OF THE INVENTION

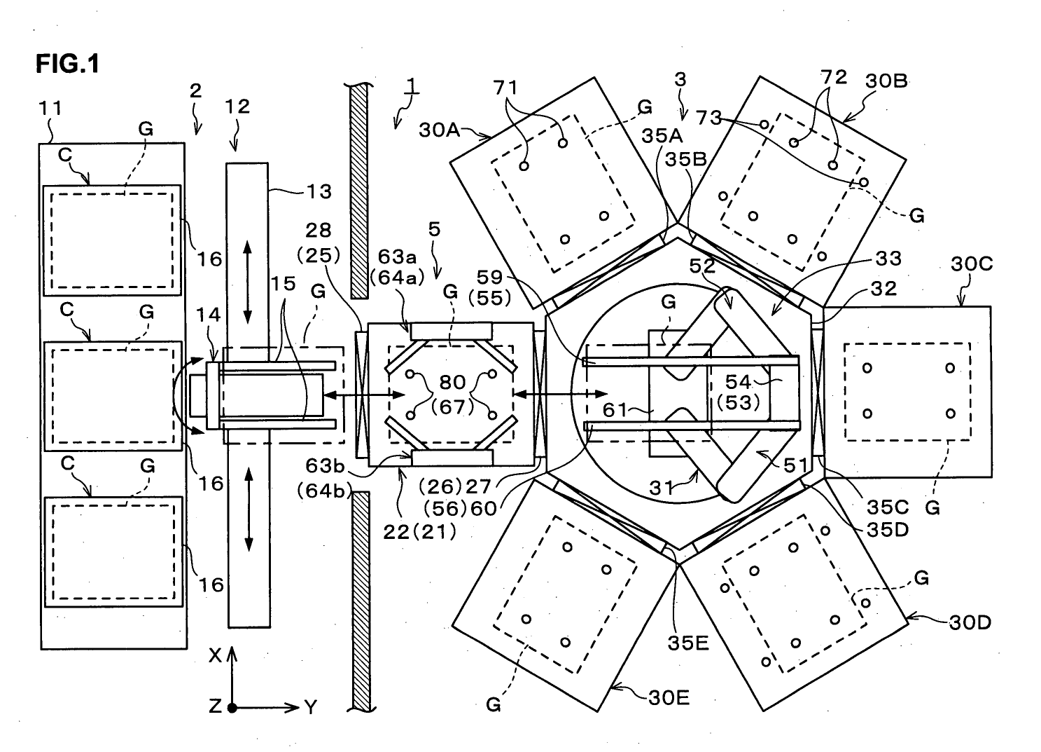

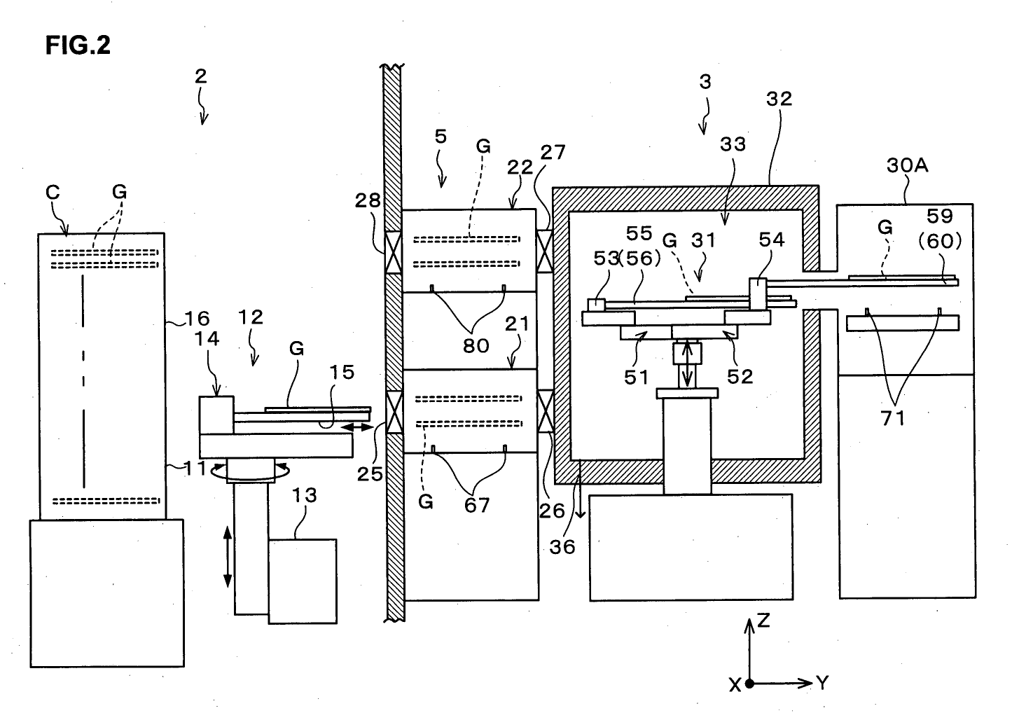

Hereinafter, an embodiment of the present invention will be described based on a substrate processing system that performs a step of forming a thin film on a LCD (Liquid Crystal Display) glass substrate G being an example of a substrate by a CVD (Chemical Vapor Deposition) process and thereafter performs an annealing step. FIG. 1 is a plane view showing a schematic configuration of a substrate processing system 1 according to the embodiment of the present invention. FIG. 2 is a side view showing a schematic configuration of the substrate processing system 1. The substrate processing system 1 shown in FIG. 1 and FIG. 2 is a so-called multi-chamber substrate processing system, and includes: a loading/unloading section 2 to carry a substrate G to/from an external part of the substrate processing system 1 and to carry a substrate G to/from a processing section 3; and the processing section 3 where a CVD process and so on are performed. A load lock device 5 is installed between the loading/unloading section 2 and the processing section 3.

The loading/unloading section 2 includes: a mounting table 11 on which cassettes C each housing a plurality of substrates G are placed; and a first carrier device 12 carrying the substrate G On the mounting table 11, the plural cassettes C are arranged in line along a substantially horizontal X-axis direction in FIG. 1. As shown in FIG. 2, the plural thin-plate substrates G in a substantially rectangular shape each taking a substantially horizontal posture are vertically stacked in each of the cassettes C placed on the mounting table 11.

The carrier device 12 is provided on a forward side in a horizontal Y-axis direction (right side in FIG. 1 and FIG. 2) of the mounting table 11. The carrier device 12 includes: a rail 13 extending along the X-axis direction; and a carrier mechanism 14 movable in the horizontal direction along the rail 13. The carrier mechanism 14 includes carrier arms 15 capable of substantially horizontally holding one substrate G and movable back and forth. The carrier arms 15 are moved up and down in a Z-axis direction (vertical direction) by the carrier mechanism 14 and supported by the carrier mechanism 14 to be rotatable in a substantially horizontal plane. Specifically, by the operation of the carrier mechanism 14, the carrier arms 15 access an opening 16 provided on a front face of each of the cassettes C on the mounting table 11 to be capable of taking out a substrate G positioned at each height or putting a substrate G to each height position one by one. Further, the carrier arms 15 access the load lock device 5 provided on a side opposite the mounting table 11 across the carrier device 12 (on the forward side in the Y-axis direction of the carrier device 12) to be capable of carrying a substrate G to/from the load lock device 5 one by one.

As shown in FIG. 2, the load lock device 5 is composed of a pair of load lock chambers, namely, a first load lock chamber 21 and a second load lock chamber 22. The first load lock chamber 21 and the second load lock chamber 22 are vertically stacked to be multistoried. In the example shown in FIG. 2, the load lock device 5 has a two-storied structure in which the second load lock chamber 22 is provided on an upper side of the first load lock chamber 21. Further, on a backward side in the Y-axis direction (left side in FIG. 2) of the load lock chamber 21, a later-described gate valve 25 opening/closing an inlet 68 of the load lock chamber 21 is provided. On the forward side in the Y-axis direction of the load lock chamber 21, a later-described gate valve 26 opening/closing an outlet 69 of the load lock chamber 21 is provided. On the forward side in the Y-axis direction of the load lock chamber 22, a later-described gate valve 27 opening/closing an inlet 82 of the load lock chamber 22 is provided. On the backward side in the Y-axis direction of the load lock chamber 22, a later-described gate valve 28 opening/closing an outlet 81 of the load lock chamber 22 is provided. In such a structure, by closing the gate valves 25, 28, an atmosphere in the loading/unloading section 2 and atmospheres in the load lock chambers 21, 22 can be shielded from each other, respectively. By closing the gate valves 26, 27, an atmosphere in the processing section 3 and the atmospheres in the load lock chambers 21, 22 can be shielded from each other, respectively. In this embodiment, a substrate G is carried into the processing section 3 from the loading/unloading section 2 via the lower load lock chamber 21, and after being processed in the processing section 3, the substrate G is carried out to the loading/unloading section 2 via the upper load lock chamber 22. The structure of the load lock chambers 21, 22 will be described in detail later.

As shown in FIG. 1, the processing section 3 includes: a plurality of, for example, five substrate processing chambers 30A to 30E in each of which a substrate G housed therein is subjected to processing such as a CVD process; and a second carrier device 31 carrying a substrate G between the load lock device 5 and each of the substrate processing chambers 30A to 30E. The processing chambers in the present invention can include the substrate processing chambers 30A to 30E and the load lock chamber 5.

The second carrier device 31 is housed in a carrier room 33 provided in a hermetic carrier chamber 32. The carrier chamber 32 is provided on the forward side in the Y-axis direction of the load lock device 5. The load lock device 5 and the substrate processing chambers 30A to 30E are disposed to surround the carrier chamber 32.

Between the carrier room 33 and the load lock chambers 21, 22, the aforesaid gate valves 26, 27 are provided respectively, and by the gate valves 26, 27, an atmosphere in the carrier room 33 and the atmospheres in the load lock chambers 21, 22 can be shielded from each other, respectively. Between the carrier room 33 and the substrate processing chambers 30A to 30E, gate valves 35A to 35E are provided respectively, and by the gate valves 35A to 35E, openings of the substrate processing chambers 30A to 30E can be closed airtight to shield the atmosphere in the carrier room 33 and atmospheres in the respective substrate processing chambers 30A to 30E from each other. As shown in FIG. 2, further provided is an exhaust path 36 through which the inside of the carrier room 33 is forcibly exhausted for pressure reduction. During processing in the substrate processing system 1, the atmospheres in the carrier room 33 and the substrate processing chambers 30A to 30E of the processing section 3 are set to a pressure lower than a pressure in the loading/unloading section 2, for example, is set to a vacuum state.

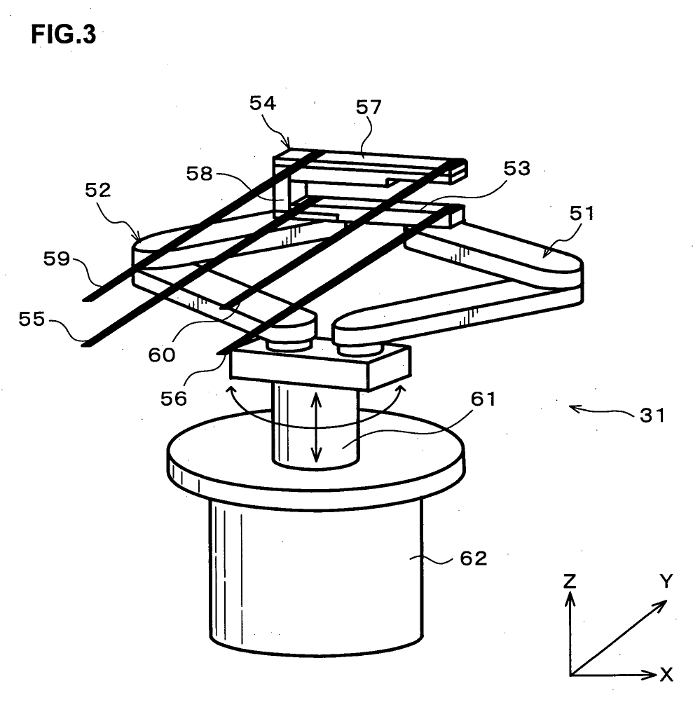

The second carrier device 31 includes, for example, two articulated-link carrier arms 51 and 52 each stretchable/contractible independently. As shown in FIG. 3, the carrier arm 51 includes a plate-shaped pin base portion 53 at its tip. On the pin base portion 53, provided are a pair of pins 55, 56 protruding in parallel to each other so as to be capable of holding one substrate G in a substantially horizontal plane. Similarly to the carrier arm 51, the carrier arm 52 includes a pin base portion 54 at its tip. The pin base portion 54 has: a plate portion 57 in substantially the same shape as that of the pin base portion 53; and a support portion 58 supporting the plate portion 57 above and in parallel to the pin base portion 53. On the plate portion 57 of the pin base portion 54, provided are a pair of pins 59, 60 protruding in parallel to each other so as to be capable of holding one substrate G in a substantially horizontal plane above the pin base portion 53. That is, the carrier arm 51 and the carrier arm 52 each are capable of simultaneously holding one substrate G in the substantially horizontal planes different in height. The pin base portions 53 and 54 are capable of slidably passing each other so as not to interfere with each other's movement when the carrier arms 51 and 52 stretch/contract while holding a substrate G or not holding a substrate G. In this embodiment, the carrier arm 51 is disposed on a lower level and the carrier arm 52 is disposed on an upper level. A support member 61 on which the carrier arms 51 and 52 are provided is supported by another support member 62 to be stretchable/contractible in the Z-axis direction and rotatable in a substantially horizontal plane. Therefore, each of the carrier arms 51 and 52 is capable of accessing the load lock chambers 21, 22 and the substrate processing chambers 30A to 30E via the gate valves 26, 27, 35A to 35E to carry a substrate G one by one thereto/therefrom.

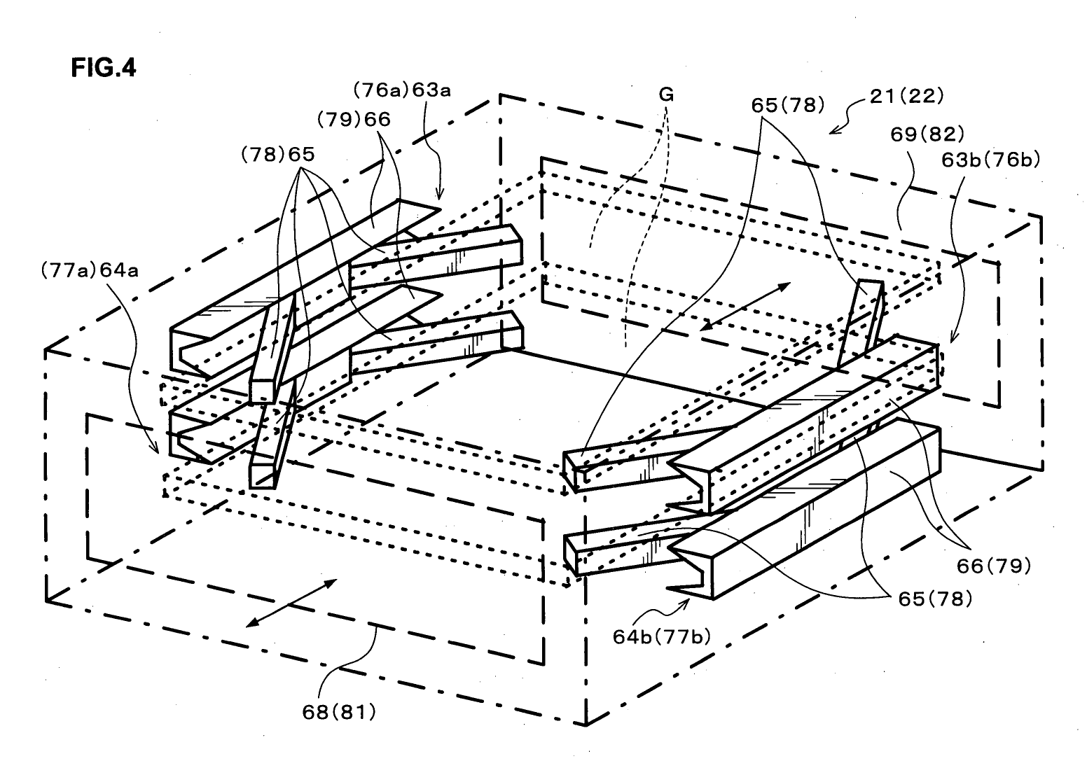

Next, the aforesaid load lock chambers 21 and 22 having the same structure will be described in detail by using the load lock chamber 21. As shown in FIG. 4, the hermetic load lock chamber 21 has substantially horizontal two-stage substrate support levels and is capable of holding two substrates G at one time therein. An upper support level is defined by a pair of hands 63a and 63b facing each other, and a lower support level is defined by a pair of hands 64a and 64b facing each other.

Each of the hands 63a, 63b, 64a, and 64b has a fixed base portion 66 to which fixed fingers 65 for supporting a substrate G are attached.

On a loading/unloading section 2 side, that is, on the backward side in the Y-axis direction, of the load lock chamber 21, the inlet 68 through which a substrate G is carried into the load lock chamber 21 is provided. The aforesaid gate valve 25 is provided in the inlet 68, so that the inlet 68 is hermetically closable by the gate valve 25. On a processing section 3 side, that is, on the forward side in the Y-axis direction, of the load lock chamber 21, the outlet 69 through which a substrate G is carried out of the load lock chamber 21 is provided. The aforesaid gate valve 26 is provided in the outlet 69, so that the outlet 69 is hermetically closable by the gate valve 26. The outlet 69 and the gate valve 26 as a transfer port of a substrate G which are provided on the processing section 3 side have a size large enough to allow the carrier arms 51 and 52 to simultaneously enter or leave the load lock chamber 21 at the time of substrate replacement by the second carrier device 31.

The load lock chamber 22 has the same structure as that of the load lock chamber 21, that is, it is capable of holding two substrates G therein at one time. An upper support level is defined by a pair of hands 76a and 76b facing each other and a lower support level is defined by a pair of hands 77a and 77b facing each other.

Each of the hands 76a, 76b, 77a, and 77b has a fixed base portion 79 to which fixed fingers 78 for supporting a substrate G are attached.

On the loading/unloading section 2 side, that is, on the backward side in the Y-axis direction, of the load lock chamber 22, provided is the outlet 81 through which a substrate G is carried out of the load lock chamber 22. In the outlet 81, the aforesaid gate valve 28 is provided, so that the outlet 81 is hermetically closable by the gate valve 28. On the processing section 3 side, that is, on the forward side in the Y-axis direction, of the load lock chamber 22, provided is the inlet 82 through which a substrate G is carried into the load lock chamber 22. In the inlet 82, the aforesaid gate valve 27 is provided, so that the inlet 82 is hermetically closable by the gate valve 27. The outlet 82 and the gate valve 27 as a transfer port of a substrate G which are provided on the processing section side 3 have a size large enough to allow the carrier arms 51 and 52 to simultaneously enter or leave the load lock chamber 22 at the time of the substrate replacement by the second carrier device 31.

Each of the substrate processing chambers 30A to 30E is appropriately structured so that predetermined substrate processing can be performed therein. A supply path (not shown) through which a predetermined process gas is supplied according to each processing and an exhaust path (not shown) through which the inside of the chamber is exhausted are connected to each of the substrate processing chambers. In this embodiment, for example, an oxide film is formed by surface layer oxidation of polysilicon and by CVD in the substrate processing chambers 30A, 30C, and 30E, and thereafter, an annealing process is performed in the substrate processing chamber 30B or 30D. The combination of processes performed in the substrate processing chambers is not limited to this, and arbitrary processes such as serial processes, parallel processes, and the like can be performed in the plural substrate processing chambers.

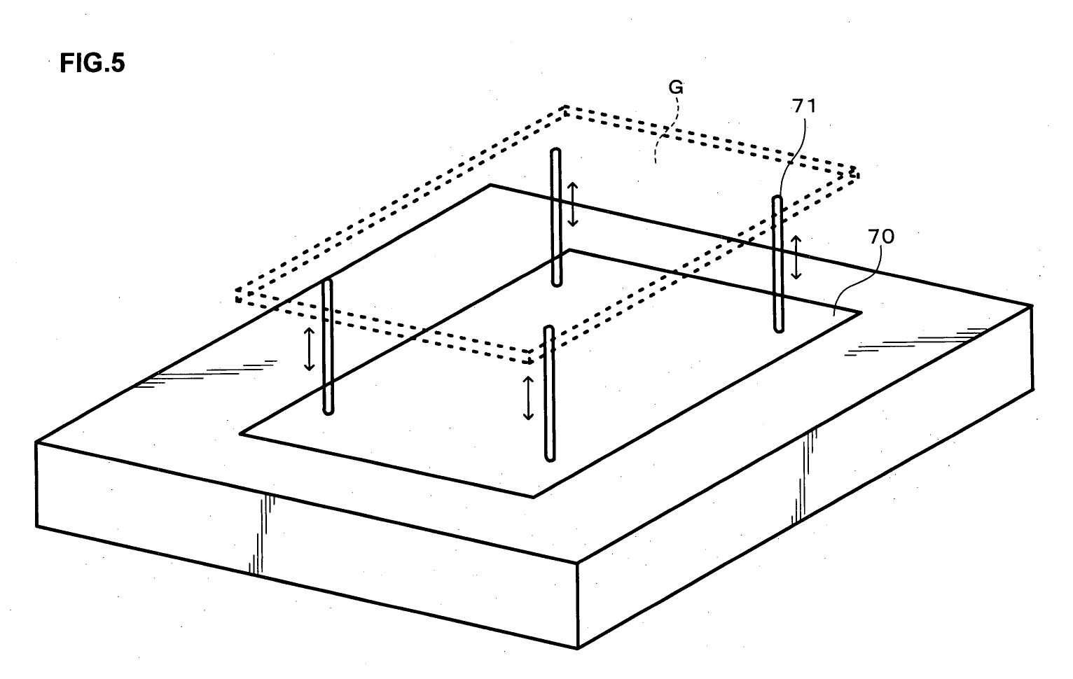

The substrate processing chambers 30A, 30C, 30E where the CVD process or the like is performed cannot have a large internal volume because of the nature of the process, and therefore, the gate valves 35A, 35C, and 35E and so on as the transfer ports of a substrate G are set small. Therefore, the second carrier device 31 is capable of making one of the carrier arms 51 and 52 enter or leave the substrate processing chambers 30A, 30C, and 30E but is not capable of making the two carrier arms 51, 52 simultaneously enter or leave the substrate processing chambers 30A, 30C, 30E. Further, inside each of the substrate processing chambers 30A, 30C, 30E, one substrate G is supported by single-stage pins. Specifically, in each of the substrate processing chambers 30A, 30C, 30E, a mounting table 70 is disposed as shown in FIG. 5. Four support pins 71 for supporting a substrate G is provided at respective corner portions of the mounting table 70. The support pins 71 can project and retract by vertical movement. In this embodiment, the support pins 71 are movable up and down in a vertical direction but may also be of a fixed type.

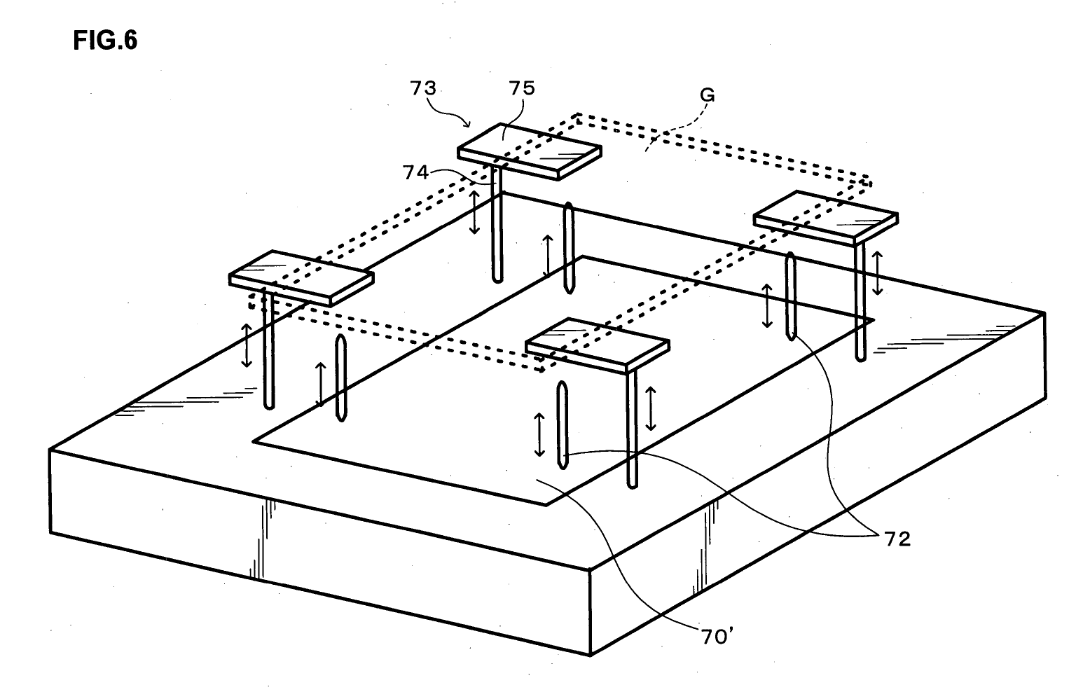

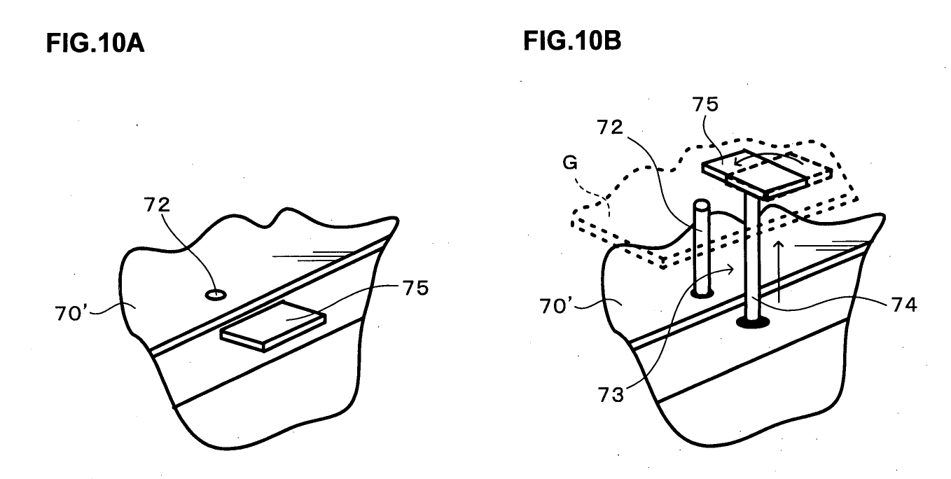

On the other hand, the substrate processing chambers 30B, 30D where the annealing process or the like is performed can have a large internal volume because of the nature of the process, and therefore, the gate valves 35B, 35D, and so on as the transfer ports of substrates G are set large. Therefore, the second carrier device 31 can make the two carrier arms 51, 52 simultaneously enter or leave the substrate processing chambers 30B, 30D at the time of substrate replacement. Further, in each of the substrate processing chambers 30B, 30D, two substrates G can be simultaneously supported by two-stage pins. That is, in each of the substrate processing chambers 30B, 30D, a mounting table 70′ shown in FIG. 6 is disposed. Four support pins 72 for supporting a substrate G is disposed at respective corner portions of the mounting table 70′. The support pins 72 can project and retract by vertical movement. Further, four support members 73 for supporting a substrate G are also disposed on the periphery of the mounting table 70′. Each of the support members 73 has a support shaft 74 projectable/retractable by vertical movement and an overhanging member 75 disposed at a tip of the support shaft 74. The support shaft 74 is rotatable together with the overhanging member 75 around a vertical axis. When the support shafts 74 are in an upward projecting state, each of the overhanging members 75 is rotated from a retracted position shown in FIG. 10(a) to a position where the overhanging member 75 projects toward the mounting table 70 side as shown in FIG. 10(b), which allows the support members 73 to support a substrate G by placing the substrate G on the overhanging members 75, so that the support members 73 support an unprocessed substrate G at a first position when receiving the substrate G Further, the support pins 72 can support a substrate G by projecting upward, and support a processed substrate G at a second position that is lower than the first position.

Next, processing steps of a substrate G in the substrate processing system 1 as structured above will be described. First, a cassette C housing a plurality of substrates G is placed on the mounting table 11 with the opening 16 facing the carrier device 12 side. Then, the carrier arms 15 of the carrier device 12 enter the opening 16 to take out one of the substrates G. The carrier arms 15 holding the substrate G is moved to a position in front of the gate valve 25 of the load lock chamber 21 disposed on the lower tier.

The inside of the load lock chamber 21 is first set to a predetermined pressure, namely, a substantially atmospheric pressure that is substantially the same as the pressure in the loading/unloading section 2, and in this state, the gate valve 25 is opened to open the inlet 68 while the outlet 69 is kept closed by the gate valve 26. Consequently, the load lock chamber 21 comes to communicate with the atmosphere in the loading/unloading section 2 via the inlet 68. Since the outlet 69 is kept closed by the gate valve 26 while the inlet 68 is opened, a vacuum state of the inside of the carrier room 33 can be maintained. In this manner, while the inlet 68 is kept open, the carrier arms 15 holding the substrate G moves in the Y-axis direction, so that the substrate G enters the load lock chamber 21 via the gate valve 25 and the inlet 68, and the unprocessed substrate G is delivered from the carrier arms 15 onto the pair of upper hands 63a, 63b or lower hands 64a, 64b facing each other. The unprocessed substrate G may be delivered to whichever of the upper and lower hands that are idle.

The substrate G is temporarily placed on the hands 63a, 63b or the hands 64a, 64b. The carrier arms 15 leave the load lock chamber 21.

In this manner, after the substrate G is carried into the load lock chamber 21 through the gate valve 25 and the inlet 68 and the carrier arms 15 leave the load lock chamber 21, the gate valve 25 is closed to bring the load lock chamber 21 into an airtight state and the inside of the load lock chamber 21 is forcibly exhausted through an exhaust path (not shown), whereby the inside of the load lock chamber 21 is set to a predetermined pressure, that is, the pressure therein is reduced to the same vacuum level as the pressure in the carrier room 33.

After the load lock chamber 21 is set to the substantially vacuum state, the gate valve 26 is opened to open the outlet 69 while the inlet 68 is kept closed by the gate valve 25. Consequently, the load lock chamber 21 comes to communicate with the atmosphere in the carrier room 33 via the outlet 69. Since the inlet 68 is kept closed by the gate valve 25 while the outlet 69 is opened, the vacuum state in the load lock chamber 21 and the carrier room 33 can be maintained.

Thereafter, the carrier arm 51 or 52 of the second carrier device 31 carries the unprocessed substrate G to the carrier room 33 from the load lock chamber 21. The unprocessed substrate G held by the carrier arm 51 or 52 is carried into, for example, the substrate processing chamber 30A, 30C, or 30E where the CVD process or the like is performed, and the substrate G is subjected to the CVD process or the like. Further, the unprocessed substrate G is carried into, for example, the substrate processing chamber 30B or 30D by the carrier arm 51 or 52 of the carrier device 31, to be subjected to the annealing process or the like there. Then, the substrate G having undergone appropriate processes in the substrate processing chambers 30A to 30E is carried into the carrier room 33 by the carrier arm 51 or 52 of the carrier device 31.

Incidentally, except for the case of the first substrate loading, a processed substrate G having been processed is present in any of the substrate processing chambers 30A to 30E, and the processed substrate G is replaced by the unprocessed substrate G when the carrier arm 51 or 52 of the carrier device 31 carries the substrate G into any of the substrate processing chambers 30A to 30E.

After the appropriate processes are finished in the respective substrate processing chambers 30A to 30E, the gate valve 28 is closed and the inside of the load lock chamber 22 is forcibly exhausted through an exhaust path (not shown), so that the pressure in the load lock chamber 22 is reduced to a vacuum state on the substantially same level as the pressure in the carrier room 33. In this substantially vacuum state, the gate valve 27 is opened to open the inlet 82 while the outlet 81 is kept closed by the gate valve 28. Consequently, the load lock chamber 22 comes to communicate with the atmosphere in the carrier room 33 via the inlet 82. Since the outlet 81 is kept closed by the gate valve 28 while the inlet 82 is opened, the vacuum state in the load lock chamber 22 and the carrier room 33 is maintained.

When the inlet 82 is thus opened, the second carrier device 31 holding the collected processed substrate G rotates to face the load lock chamber 22. While rotating, the second carrier device 31 moves up or down the carrier arms 51, 52 as required up to a position corresponding to the height of the inlet 82. At this time, the second carrier device 31 is holding the processed substrate G by the pins 55, 56 of the carrier arm 51 or by the pins 59, 60 of the carrier arm 52, and the other pair of pins are not holding any substrate G. The processed substrate G is carried into the load lock chamber 22 from the carrier room 33 of the processing section 3 through the inlet 82 and the gate valve 27.

After the second carrier device 31 makes the pins 55, 56 of the carrier arm 51 and the pins 59, 60 of the carrier arm 52 leave the load lock chamber 22, the inlet 82 is closed by the gate valve 27 and the inside of the load lock chamber 22 is set to the atmospheric pressure. After the inside of the load lock chamber 22 is set to the substantially atmospheric pressure, the outlet 81 is opened by opening the gate valve 28 while the inlet 82 is kept closed by the gate valve 27. Consequently, the load lock chamber 22 comes to communicate with the atmosphere in the loading/unloading section 2 via the outlet 81. Since the inlet 82 is kept closed by the gate valve 27 while the outlet 81 is opened, the vacuum state in the carrier room 33 can be maintained.

Next, the carrier arms 15 of the carrier device 12 are moved in the Y-axis direction to enter the load lock chamber 22 via the gate valve 28 and the outlet 81. At this time, the height of the carrier arms 15 is adjusted so that they can collect the processed substrate G placed on the upper hands 76a, 76b or the lower hands 77a, 77b of the load lock chamber 22. After the adjustment, the carrier arms 15 enter the load lock chamber 22 to receive the processed substrate G held on the pair of upper hands 76a, 76b or lower hands 77a, 77b of the load lock chamber 22. The carrier arms 15 holding the processed substrate G enter the opening 16 of a predetermined one of the cassettes C to place the processed substrate G therein. In the above-described manner, a series of the processing steps in the processing system 1 is finished.

The above embodiment has described the example where a substrate G is carried into the processing section 3 from the loading/unloading section 2 via the lower load lock chamber 21, and after processed in the processing section 3, the substrate G is carried out to the loading/unloading section 2 via the upper load lock chamber 22. However, it should be noted that the scope of the present invention also includes a case where a substrate G is carried into the processing section 3 via the upper load lock chamber 22, and after processed in the processing section 3, the substrate G is carried out to the loading/unloading section 2 via the lower load lock chamber 21. The scope of the present invention also includes a case where a substrate G is carried into the processing section 3 via the lower load lock chamber 21, and after processed in the processing section 3, the substrate G is carried out to the loading/unloading section 2 via the lower load lock chamber 21. The scope of the present invention also includes a case where a substrate G is carried into the processing section 3 via the upper load lock chamber 22, and after processed in the processing section 3, the substrate G is carried out to the loading/unloading section 2 via the upper load lock chamber 22.

The load lock chamber may be any of a two-storied type such as the load lock chambers 21, 22 shown in the drawings, a three-storied type, and a one-storied type.

In the structure where two substrates G is simultaneously holdable in each of load lock chambers 21, 22 as in the shown load lock chambers 21, 22, an unprocessed substrate G that is to be processed in the processing section 3 and a processed substrate G having been processed in the processing section 3 may be simultaneously held in the load lock chamber 21 and/or the load lock chamber 22. In this case, the carriage of the substrate G from the loading/unloading section 2 to the load lock chamber 21 and/or the load lock chamber 22 may coincide with the carriage of the substrate G from the load lock chamber 21 and/or the load lock chamber 22 to the loading/unloading section 2. Further, the carriage of the substrate G from the load lock chamber 21 and/or the load lock chamber 22 to the processing section 3 may coincide with the carriage of the substrate G from the processing section 3 to the load lock chamber 21 and/or the load lock chamber 22.

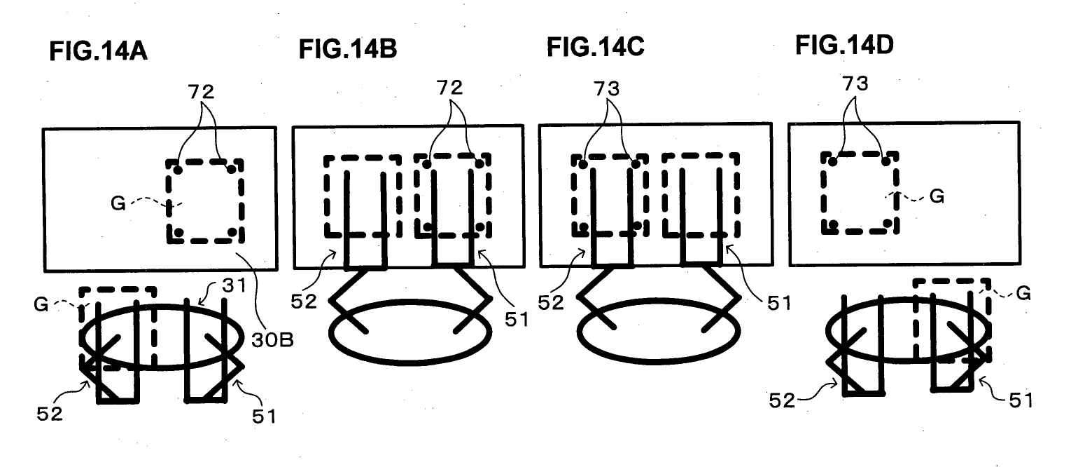

Here, the carriage of substrates G to/from the substrate processing chambers 30B, 30D by the second carrier device 31 will be described. In this embodiment, each of the substrate processing chambers 30B, 30D is structured to support two substrates G therein at one time by the two-stage pins, and in each of these substrate processing chambers 30B, 30D, substrates G can be replaced by a first procedure where the carrier arms 51 and 52 of the second carrier device 31 simultaneously enter and simultaneously leave. The first procedure takes the steps shown in FIG. 14(a) to FIG. 14(d). In FIG. 14(a) to FIG. 14(d), the substrates G held by the carrier arms 51, 52 are shown on the right and left for easier view, but the substrates G held by the carrier arms 51, 52 are at the same position when viewed from above.

The substrate replacement in the substrate processing chamber 30B by the first procedure will be described. It is assumed that, in a state prior to the substrate replacement, the second carrier device 31 is holding an unprocessed substrate G, which is to be processed in the substrate processing chamber 30B, on the pins 59, 60 of the upper carrier arm 52 and is not holding any substrate G on the pins 55, 56 of the lower carrier arm 51. The second carrier device 31 rotates to face the substrate processing chamber 30B being a predetermined target chamber where the annealing process is performed (FIG. 14(a)). When rotating, the second carrier device 31 moves the carrier arms 51, 52 up or down as required to bring them to the height corresponding to the gate valve 35B connected to the substrate processing chamber 30B.

Then, in the substrate processing chamber 30B, while one processed substrate G having undergone the processing in the substrate processing chamber 30B is placed on the mounting table 70′, the support members 73 project upward from the state in FIG. 10(a). Further, as shown in FIG. 10(b), the support shafts 74 are rotated so that the overhanging members 75 project toward the mounting table 70 side. In this state, the support members 73 have not yet held any substrate G, and is in a state of capable of placing the unprocessed substrate G on the overhanging members 75 to receive it at a first position on an upper level.

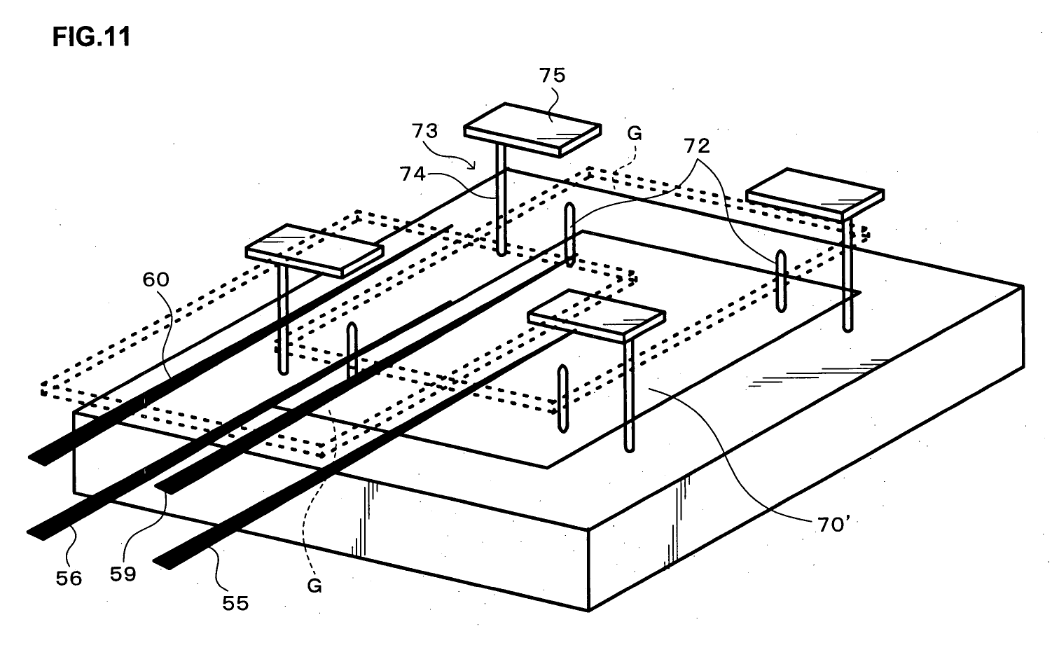

Next, the support pins 72 are projected upward to raise the processed substrate G, thereby supporting the processed substrate G at a second position on a lower level. Through the above-described operations, the state in FIG. 11 is produced. In this case, the height of the second carrier device 31 is adjusted so that the pins 55, 56 of the lower carrier arm 52 come to a position corresponding to the second position and the pins 59, 60 of the upper carrier arm 52 come to a position corresponding to the first position. Further, the pins 59, 60 of the carrier arm 52 are holding the unprocessed substrate G that is to be processed in the substrate processing chamber 30B.

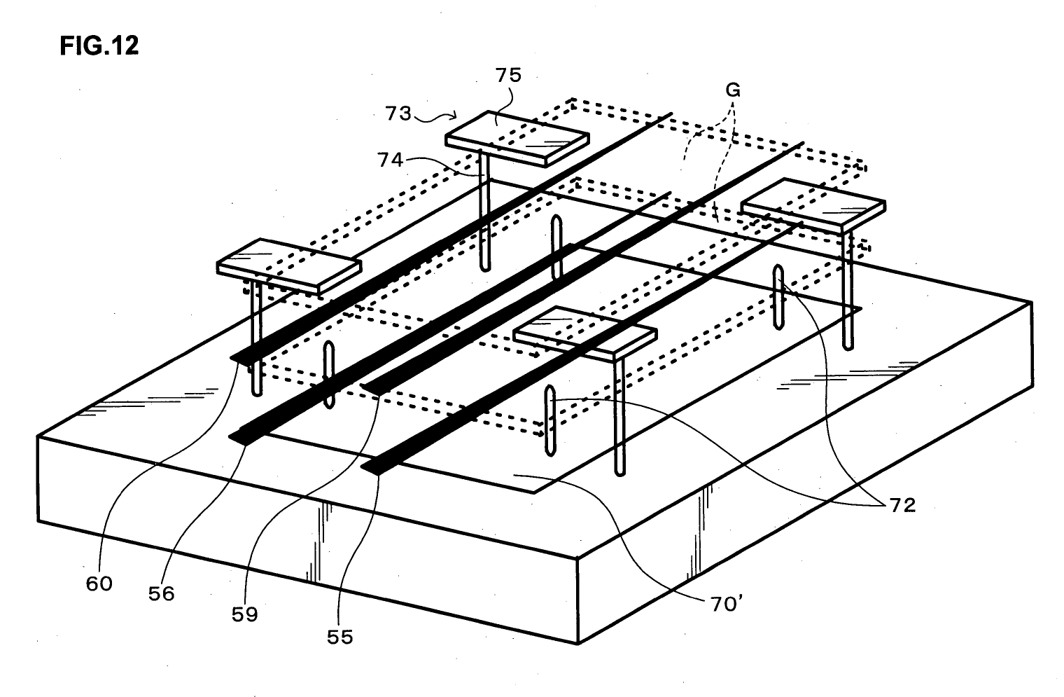

Next, as shown in FIG. 12, the carrier arms 51 and 52 are stretched at the same time to move forward to a position above the mounting table 70′, and the unprocessed substrate G is carried to the first position above the mounting table 70′ (FIG. 14(b)). In this case, the pins 55, 56 of the carrier arm 51 are positioned right under the processed substrate G that is at the second position. In this state, the support shafts 74 of the support members 73 are slightly moved up and at the same time, the support pins 72 are moved down. Consequently, the unprocessed substrate G comes to be mounted on the support members 73 and the processed substrate G comes to be held on the pins 55, 56 of the carrier arm 51 (FIG. 14(c)).

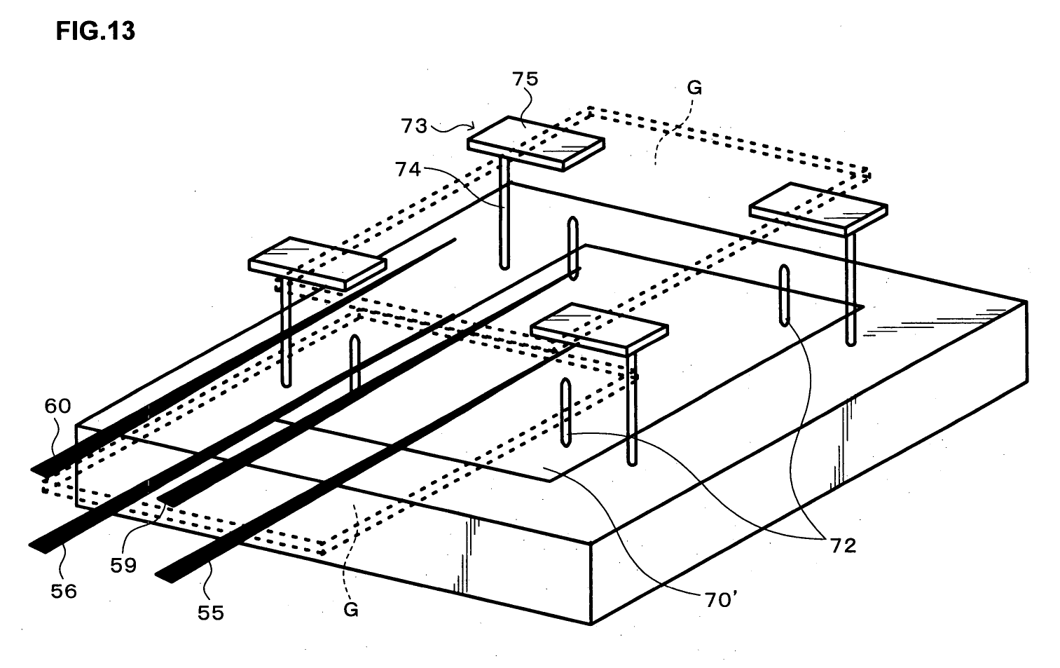

Thereafter, as shown in FIG. 13, the carrier arm 51 with the processed substrate G being placed on the pins 55, 56 thereof is contracted to leave the substrate processing chamber 30B (FIG. 14(d)). Further, the carrier arm 52 is also contracted at the same time.

Then, as shown in FIG. 6, the support pins 72 are moved upward again to support the unprocessed substrate G, and the support members 73 are moved down to be returned to the state in FIG. 10(a). Along with the operation in FIG. 6, the operation of closing the gate valve 35B between the substrate processing chamber 30B and the carrier room 33 is started, and after the substrate processing chamber 30B is hermetically closed, O₂ or the like is supplied through the supply path (not shown) to anneal the substrate G Though the substrate replacement in the substrate processing chamber 30B has been described, it should be noted that the substrate replacement in the substrate processing chamber D similarly follows the first procedure.

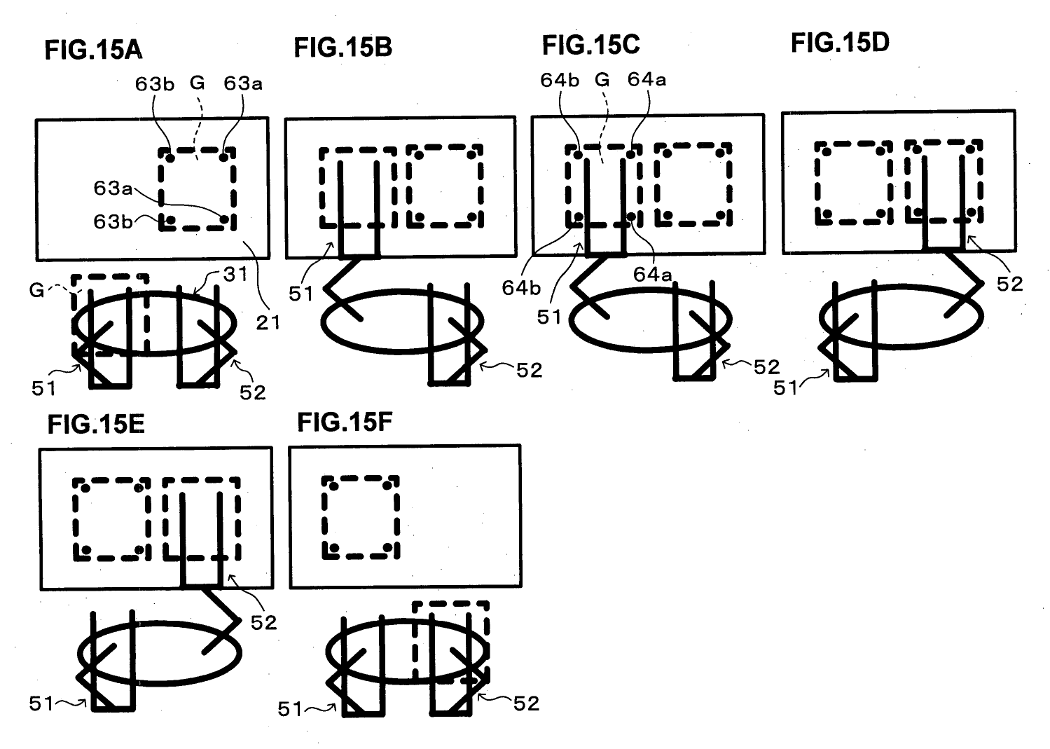

Next, the carriage of substrates G to/from the load lock chambers 21, 22 by the second carrier device 31 will be described. This embodiment will describe a case where substrates G are replaced in the load lock chambers 21, 22 by a second procedure where the carrier arms 51, 52 of the carrier device 31 enter/leave at different timings. The second procedure takes the steps shown in FIG. 15(a) to FIG. 15(f). In FIG. 15(a) to FIG. 15(f), the substrates G held by the carrier arms 51, 52 are shown on the right and left for easier view, but the substrates G held by the carrier arms 51, 52 are at the same position when viewed from above.

The substrate replacement in the load lock chamber 21 by the second procedure will be described. It is assumed that the second carrier device 31 is holding a processed substrate G, which has been processed in the processing section 3, on the pins 55, 56 of the lower carrier arm 51 and is not holding any substrate G on the pins 59, 60 of the upper carrier arm 52. The second carrier device 31 rotates to face the load lock chamber 21 being a target chamber (FIG. 15(a)). When rotating, the second carrier device 31 moves up or down the carrier arms 51, 52 as required to bring them to the height corresponding to the gate valve 26 and the outlet 69. The carrier arm 51 is stretched in the Y-axis direction to enter the load lock chamber 21 via the gate valve 26 and the outlet 69 (FIG. 15(b)). In this case, it is assumed that, in the load lock chamber 21, an unprocessed substrate G which is to be processed in the processing section 3 is held on the pair of hands 63a and 63b and no substrate G is held on the pair of hands 64a and 64b. At this time, the pins 55, 56 of the carrier arm 51 are positioned between the hands 63a, 63b and hands 64a, 64b of the load lock chamber 21.

Next, the carrier arm 51 is moved down to place the unprocessed substrate G, which is held by the pins 55, 56 of the carrier arm 51, on the hands 64a and 64b (lower support level) (FIG. 15(c)). The carrier arm 51 not holding any substrate G is contracted to leave. Concurrently with the contraction of the carrier arm 51, the carrier arm 52 not holding any substrate G is stretched to enter the load lock chamber 21 (FIG. 15(d)). At this time, the pins 59, 60 of the carrier arm 52 are positioned between the hands 63a, 63b and 64a, 64b of the load lock chamber 21. The carrier arm 52 is moved up so that the unprocessed substrate G held by the hands 63a, 63b comes to be supported and held on the pins 59, 60 of the carrier arm 52 (FIG. 15(e)). The carrier arm 52 holding the unprocessed substrate G is contracted to leave the load lock chamber 21. In this manner, the unprocessed substrate G is carried out of the load lock chamber 21 through the outlet 69 and the gate valve 26 to be carried into the carrier room 33 of the processing section 3. It should be noted that, though the substrate replacement in the load lock chamber 21 is described, the substrate replacement in the load lock chamber 22 similarly follows the second procedure.

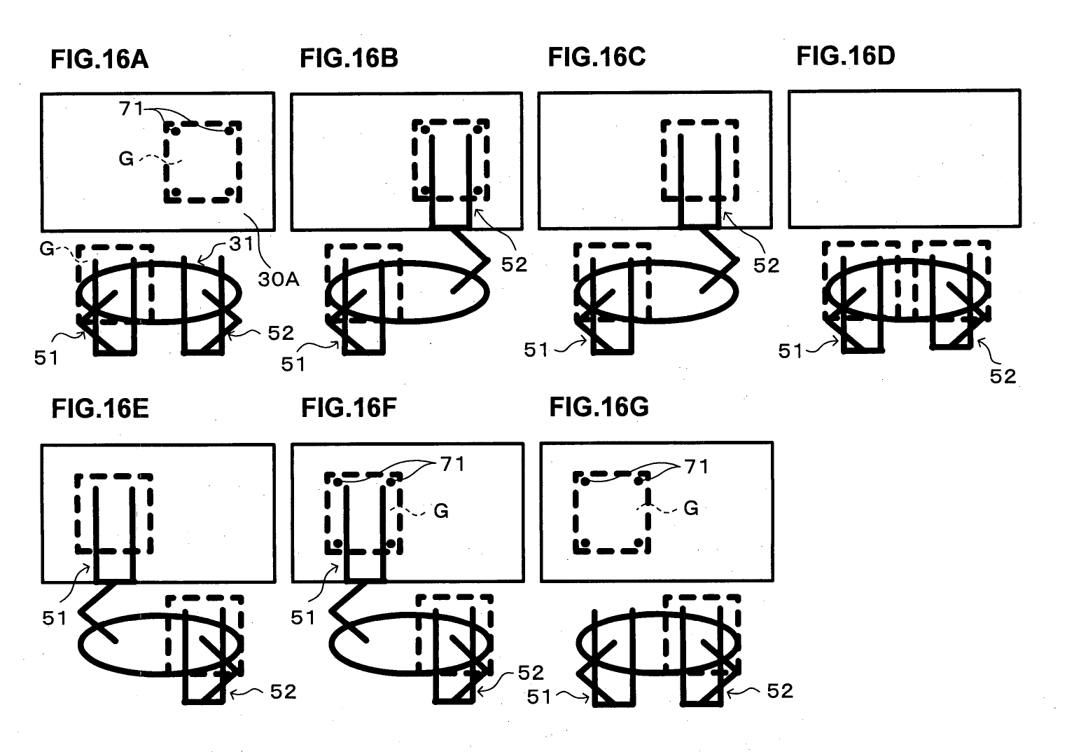

Next, the carriage of substrates G to/from the substrate processing chambers 30A, 30C, 30E by the second carrier device 31 will be described. In this embodiment, each of the substrate processing chambers 30A, 30C, 30E is structured to support one substrate G therein by the single-stage pin and a substrate G can be replaced by another by a third procedure where the carrier arms 51 and 52 of the second carrier device 31 enter/leave at different timings. The third procedure takes the steps shown in FIG. 16(a) to FIG. 16(g). In FIG. 16(a) to FIG. 16(g), the substrates G held by the carrier arms 51, 52 are shown on the right and left for easier view, but the substrates G held by the carrier arms 51, 52 are at the same position when viewed from above.

The substrate replacement in the substrate processing chamber 30A by the third procedure will be described. The third procedure is similar to the second procedure, but in the second procedure, the leaving of the carrier arm 52 and the entrance of the carrier arm 51 coincide with each other (FIG. 15(c) and FIG. 15(d)). On the other hand, in the third procedure, the leaving of the carrier arm 52 and the entrance of the carrier arm 51 take place at different timings (FIG. 16(c), FIG. 16(d), and FIG. 16(e)). It is assumed that the second carrier device 31 is holding an unprocessed substrate G, which is to be processed in the substrate processing chamber 30A, on the pins 55, 56 of the lower carrier arm 51 and is not holding any substrate G on the pins 59, 60 of the upper carrier arm 52. The second carrier device 31 rotates to face the substrate processing chamber 30A (FIG. 16(a)). When rotating, the second carrier device 31 moves the carrier arms 51, 52 up or down as required to bring the carrier arm 52 to the height corresponding to the gate valve 35A connected to the substrate processing chamber 30A.

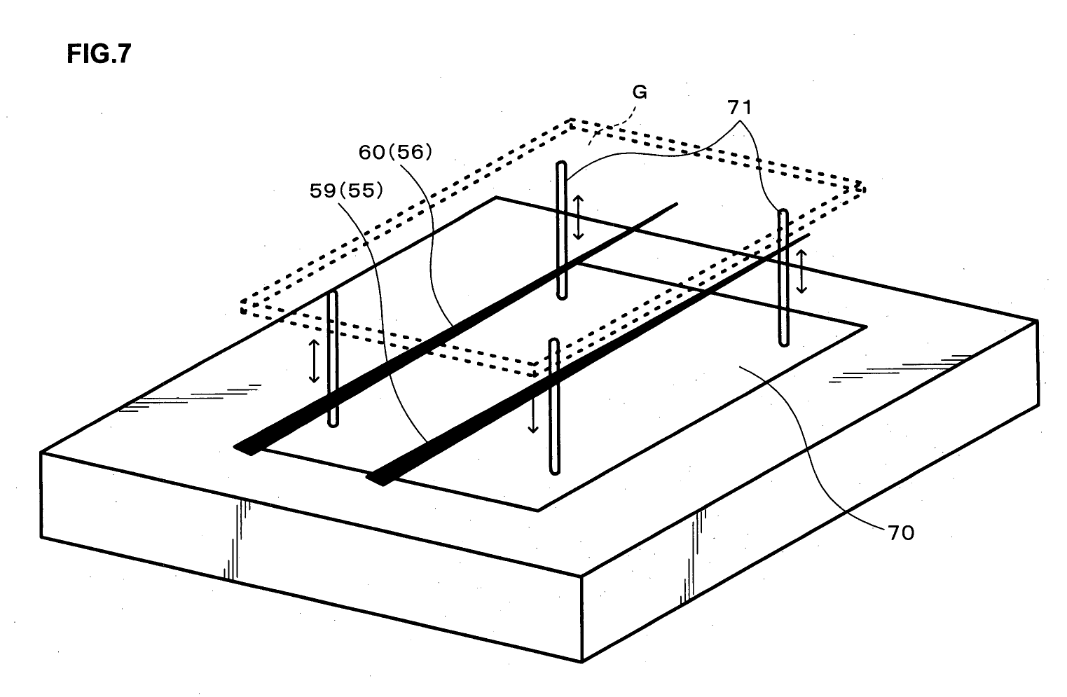

First, in the substrate processing chamber 30A, the support pins 71 are moved upward while an unprocessed substrate G is placed on the mounting table 70, so that the processed substrate G is supported by the support pins 71 as shown in FIG. 5. In this state, the carrier arm 52 not holding any substrate G is first stretched to bring the pins 59, 60 provided at the tip thereof to a position under the processed substrate G in the substrate processing chamber 30A as shown in FIG. 7 (FIG. 16(b)).

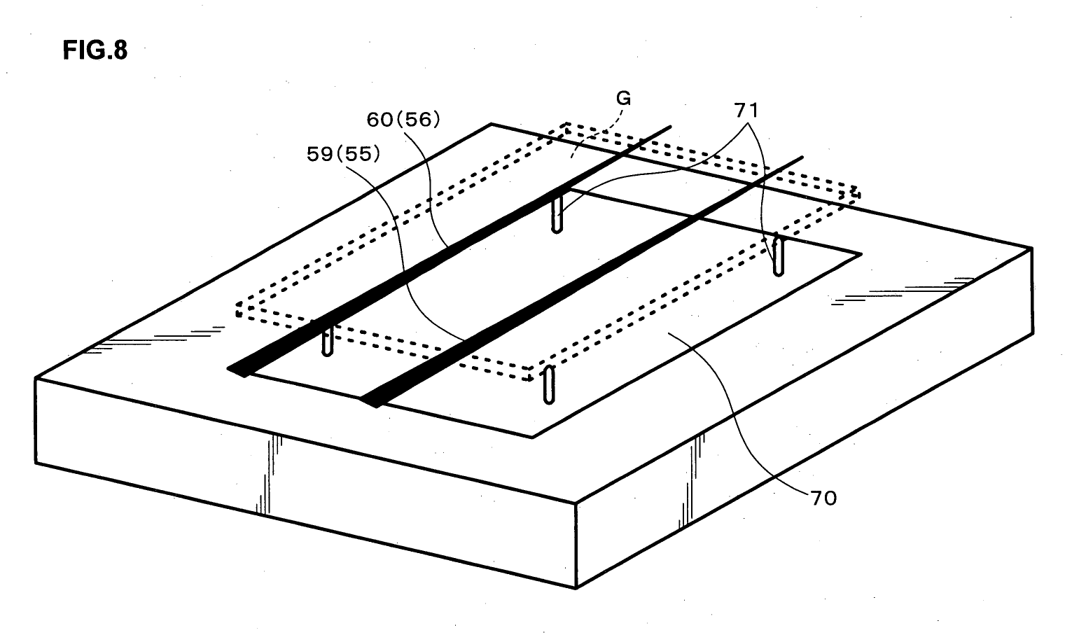

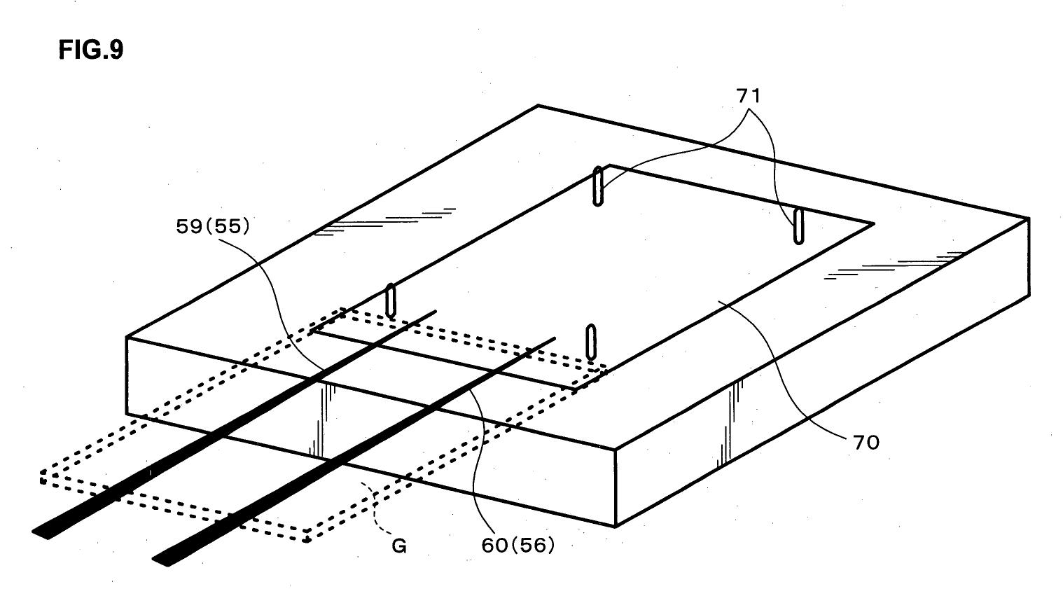

Subsequently, the support pins 71 are moved down, so that the processed substrate G comes to be supported and held on the pins 59, 60 of the carrier arm 52 as shown in FIG. 8 (FIG. 16(c)). The carrier arm 52 holding the processed substrate G on the pins 59, 60 thereof is contracted to leave the substrate processing chamber 30A as shown in FIG. 9 (FIG. 16(d)). Next, the carrier arms 51, 52 are raised so that the carrier arm 51 reaches a position corresponding to the height of the gate valve 35A. The carrier arm 51 holding the unprocessed substrate G on the pins 55, 56 is stretched to carry the unprocessed substrate G to a position above the support pins 71 as shown in FIG. 8 (FIG. 16(e)). The support pins 71 are projected upward, so that the unprocessed substrate G is transferred from the pins 55, 56 of the carrier arm 51 to the support pins 71 to be supported on the pins 71 as shown in FIG. 7 (FIG. 16(f)).

Next, the carrier arm 51 is contracted to leave the substrate processing chamber 30A and at the same time, the pins 71 supporting the unprocessed substrate G move down, so that the unprocessed substrate G is placed on the mounting table 70 (FIG. 16(g)). The operation of closing the gate valve 35A between the substrate processing chamber 30A and the carrier room 33 is started, and after the substrate processing chamber 30A is hermetically closed, O₂ is first supplied through the supply path (not shown), whereby the substrate G is surface-oxidized. Subsequently, gas such as silane, O₂, or Ar is supplied through the supply path (not shown) and a SiO₂ oxide film is formed on the substrate G by a CVD process. It should be noted that, though the substrate replacement in the substrate processing chamber 30A is described, the substrate replacement in the substrate processing chambers 30C, 30E similarly follows the third procedure.

In the above-described embodiment, in the multi-chamber substrate processing system having the carrier device that includes the first and second arms each capable of holding a substrate and carries the substrates to/from the plural chambers, the following two states are switchable according to the kind of chambers where the substrate replacement is performed, that is, the state where the first and second arms simultaneously enter the processing chamber and the state where the first and second arms enter the processing chamber at different timings. This improves throughput of a substrate processing system where a first-stage and a second-stage chamber can both exist.

Further, in the above-described embodiment, in the multi-chamber substrate processing system that includes the first and second arms each capable of holding a substrate and carries the substrates to/from the plural chambers, the first and second arms concurrently enter a substrate chamber for the annealing process or the like having a large substrate transfer port, so that the step of carrying the substrate out of the chamber by the first arm and the step of carrying the substrate into the chamber by the second arm coincide with each other. This reduces the substrate carriage time. Similarly, the operation of the first arm to leave the load lock chamber whose substrate transfer port is set large and the operation of the second arm to enter the load lock chamber coincide with each other, so that the substrate carriage time is reduced. Thus reducing the substrate carriage time improves throughput of a substrate processing system where a single-stage chamber and a two-stage chamber can both exist. Further, in the substrate processing system, it is also possible to start the operation of the second arm to enter the chamber after the operation of the first arm to leave the chamber is completed, so that the substrate transfer port of the substrate processing chamber where the CVD process or the like is performed can be set small.

Hitherto, a preferable embodiment of the present invention has been described with reference to the attached drawings, but the present invention is not limited to such an example. It is obvious that those skilled in the art could reach modification examples and corrected examples of various kinds within the range of the technical ideas described in the claims, and it is to be understood that these examples naturally belong to the technical scope of the present invention.

In the above-described embodiment, in a case where a load lock chamber or a substrate chamber is of a single-stage type, the substrate replacement therein follows the aforesaid third procedure, but may follow the aforesaid second procedure.

Further, in the above-described embodiment, the two-stage load lock chamber is taken as an example of the load lock chamber, but the load lock chamber may be a single-stage load lock chamber.

In the above-described embodiment, the two-storied load lock chambers, that is, the load lock chambers stacked in two tiers, are described, but the load lock chamber may be a one-storied load lock chamber or multi-stored load lock chambers.

Further, in the above-described embodiment, as a single-stage substrate processing chamber, the substrate processing chamber where the CVD process or the like is performed is taken as an example, but the single-stage substrate processing chamber may be a substrate processing chamber where, for example, a plasma CVD process, a sputtering process, or the like is performed.

In the above-described embodiment, as the two-stage substrate processing chamber, the substrate processing chamber where the annealing process or the like is performed is taken as an example, but the two-stage substrate processing chamber may be a substrate processing chamber where, for example, an etching process, an ashing process, or the like is performed.

In the above-described embodiment, as the single-stage chamber, the single-stage chamber where the substrate is supported by using the pins is taken as an example, but a single-stage chamber where the substrate is supported by other mechanism in a single-stage manner may be used.

In the above-described embodiment, as the two-stage chamber, the two-stage chamber in which the substrates are supported in two tiers by using the hands and the two-stage chamber in which the substrates are supported in two tiers by using the pins are taken as examples, but a two-stage chamber in which substrates are supported in two tiers by other mechanism may be used.

According to the present invention, in a multi-chamber substrate processing system in which one substrate processing chamber or more of a single-stage type and one substrate processing chamber or more of a two-stage type can both exist, throughput can be improved.

What is claimed is:

1. A substrate processing system comprising: a processing chamber where a substrate is processed; and a carrier device carrying the substrate to/from said processing chamber,
wherein said carrier device includes at least two arms each capable of holding a substrate and is capable of switching a state of making the two arms enter said processing chamber simultaneously and a state of making the two arms enter said processing chamber at different timings.

2. The substrate processing system according to claim 1,
wherein said processing chamber is provided in plurality, and the two arms are made to simultaneously enter part of said processing chambers and the two arms are made to enter the other part of said processing chambers at different timings.

3. A substrate processing method using a substrate processing system that includes: a processing chamber where a substrate is processed; and a carrier device carrying the substrate to/from the processing chamber,
wherein the carrier device includes at least two arms each capable of holding a substrate and is capable of switching a state of making the two arms simultaneously enter the processing chamber and a state of making the two arms enter the processing chamber at different timings, and
wherein steps of making the two arms enter the processing chamber coincide with each other.

4. The substrate processing method according to claim 3, wherein steps of making the two arms leave the processing chamber coincide with each other.

5. A substrate processing method using a substrate processing system that includes: a processing chamber where a substrate is processed; and a carrier device carrying the substrate to/from the processing chamber,
wherein the carrier device includes at least two arms each capable of holding a substrate and is capable of switching a state of making the two arms simultaneously enter the processing chamber and a state of making the two arms enter the processing chamber at different timings, and
wherein steps of making the two arms enter the processing chamber take place at different timings.

6. The substrate processing method according to claim 5, wherein a step of making one of the two arms enter the processing chamber and a step of making the other arm leave the processing chamber coincide with each other.

7. The substrate processing method according to claim 5, wherein a step of making one of the two arms enter the processing chamber and a step of making the other arm leave the processing chamber take place at different timings.

8. A substrate processing method using a substrate processing system that includes: a plurality of processing chambers in each of which a substrate is processed; and a carrier device carrying the substrate to/from the processing chambers,
wherein the carrier device includes at least two arms each capable of holding a substrate and is capable of switching a state of making the two arms simultaneously enter each of the processing chambers and a state of making the two arms enter each of the processing chambers at different timings, and
wherein the two arms are made to simultaneously enter part of the processing chambers and the two arms are made to enter the other part of the processing chambers at different timings.

9. The substrate processing method according to claim 8, wherein a step of making one of the two arms enter the other part of the processing chambers and a step of making the other arm leave the other part of the processing chambers coincide with each other.

10. The substrate processing method according to claim 8, wherein a step of making one of the two arms enter the other part of the processing chambers and a step of making the other arm leave the other part of the processing chambers take place at different timings.
